(19) United States
(12) Patent Application Publication
(10) Pub. No.: US 2008/0149160 A1
(43) Pub. Date: Jun. 26, 2008

(54) Photovoltaic Cell Based on Vectorial Electron Transfer

(75) Inventors: Helge Lemmetyinen, Tampere (FI); Nikolai Tkachenko, Tampere (FI); Alexander Efimov, Tampere (FI); Elina Vuorimaa, Tampere (FI); Tommi Vuorinen, Tampere (FI); Vladimir Chucharev, Tampere (FI)

Correspondence Address: SUGHRUE MION, PLLC, 2100 PENNSYLVANIA AVENUE, N.W., SUITE 800, WASHINGTON, DC, 20037, US

(73) Assignee: LICENTIA OY, Helsinki (FI)

(21) Appl. No.: 11/660,107

(22) PCT Filed: Aug. 18, 2005
(86) PCT No.: PCT/FI05/00355

§ 371 Date: Feb. 14, 2008

(30) Foreign Application Priority Data
Aug. 18, 2004 (FI) 20041087

(51) Int. Cl. H01L 51/46; C23C 14/00; C23C 16/44; B05D 1/18; B05D 1/00

(52) U.S. Cl. 136/244; 136/263; 136/252; 427/74; 136/265; 977/734

(57) ABSTRACT

A photovoltaic device and a method for production thereof. The photovoltaic device comprises an anode (32), a cathode (46) spaced apart from the anode, and at least one subcell disposed between the anode and the cathode. The subcell comprises a charge-transfer dyad (38) with a light absorbing electron donor moiety (40) and an electron acceptor moiety (42), which are covalently linked to each other in a non-flexible configuration and oriented such that each subcell is capable of performing primary photo-induced vectorial electron transfer between the donor and acceptor moieties in the direction from the anode to cathode. The structure of the donor-acceptor molecule is highly symmetric, which greatly increases the intramolecular electron transfer probability and, thereby, the efficiency of the device.

### BACKGROUND OF THE INVENTION

1. Field of the Invention

The present invention relates to organic photovoltaic devices, e.g. organic solar cells, comprising a plurality of molecular layers stacked in a series. Such a stack typically comprises at least one intermediate layer, which consists of compounds containing electron donating and accepting moieties.

2. Description of Related Art

Photovoltaic (also abbreviated “PV”) cells convert electromagnetic radiation into electricity. Thus, solar cells, which are examples of typical photovoltaic cells, are used to generate electrical power from ambient light.

Photosensitive optoelectronic devices have mostly been constructed of a number of inorganic semiconductors (silicon, gallium arsenide, cadmium telluride, etc.). Devices utilizing amorphous silicon have reached efficiencies of 25% or more. Commercially available silicon cells have efficiencies in the range of 4 to 8%. These devices, especially when they are shaped into panels having a large surface area, are difficult and expensive to produce. Recently, efforts have therefore been focused on the use of organic photovoltaic cells to achieve satisfactory photovoltaic conversion efficiencies at economically reasonable costs.

When an organic material suitable for an optical device is irradiated with appropriate light a photon is absorbed by a molecular component of the material and, as a result, an excited state of the molecular component is produced: an electron is promoted from the HOMO (highest occupied molecular orbital) state to the LUMO (lowest unoccupied molecular orbital) state of the molecule, or a hole is promoted from the LUMO to the HOMO. Thus, an exciton, i.e. an electron-hole pair state is generated. This exciton state has a natural life-time before the electron and the hole will recombine. In order to create a photocurrent the components of the electron-hole pair have to be separated, i.e. the life-time of the pair has to be considerably increased. The separation can be achieved by juxtaposing two layers of materials with different conductive properties. The materials can be either of the n-, or donor-types, or p-, or acceptor-types. The interface between the layers forms a photovoltaic heterojunction and it should have an asymmetric conduction characteristic, i.e., it should be capable of supporting electronic charge transport preferably in one direction.

An organic bilayer system forms a typical photovoltaic cell where the charge separation predominantly occurs at the heterojunction. It is known in the art to form the heterojunctions from, e.g., two different conjugated polymers (U.S. Pat. No. 5,670,791). The conjugated polymers include semiconductive polymers such as polyphenylene, poly(vinyl phenylene), polythiophene and polyaniline. The photoresponsive zone of the reference is formed by a polymer blend with two phase-separated polymers, of which the second has a greater electron affinity than the first one. In use of the device, electrons will be traveling predominantly through the second semiconductive polymer and holes travelling predominantly through the first semiconductive polymer.

Organic PV cells have many advantages when compared to silicon-based devices: they are light-weight, inexpensive and flexible. They have, however, relatively low quantum yields, being of the order of 1 to 3% or less. Different approaches to increasing the efficiency have been demonstrated, which mostly are based on layer configurations producing interlayer heterojunctions supporting the preferred charge transfer.

Examples of improved organic photovoltaic cells are disclosed in U.S. Pat. Nos. 5,331,183 and 5,454,880, in which the heterojunction is formed by semiconducting, conjugated polymer donors and the acceptor component by fullerenes, particularly Buckminsterfullerenes, C₆₀. A similar structure is disclosed in Published International Patent Application No. WO 01/84644. The particular advantage of using fullerenes is that the combination of charge carriers can be avoided, whereby efficiency is greatly improved.

Further improved PV cells are discussed in US Patent Application Publication No. 2002/0189666, which comprises in combination: an anode layer, an organic hole transporting (donor-type) layer, an electron transporting (acceptor-type) layer comprising fullerene, a cathode and at least one exciton blocking layer between the acceptor and the cathode for improving quantum efficiency. According to the application, power conversion efficiencies in excess of 4% have been attained.

In spite of the above-described improvements, there is still a need for new efficient organic photovoltaic cells.

### SUMMARY OF THE INVENTION

It is an aim of the present invention to provide a novel multilayered structure with organic molecules stacked in a series to produce a photovoltaic cell, in which light energy is efficiently changed into electrical energy.

It is another aim of the invention to provide a method of producing a photovoltaic cell comprising a multilayered structure of organic molecules.

It is a third aim of the invention to provide a method for the production of electricity from light.

These and other objects, together with the advantages thereof over the known photovoltaic cells and methods for the production thereof, which shall become apparent from specification which follows, are accomplished by the invention as hereinafter described and claimed.

The present invention is based on the idea of creating intramolecular charge transfer with high efficiency by orienting organic molecules as molecular films or layers in order to achieve a vectorial electron transfer zone as the primary step in the consecutive processes following light absorption, e.g. by a light absorbing layer formed by a conjugated organic polymer. The organic molecular layers providing vectorial electron transfer comprise a combination of a light absorbing electron donor moiety, such as a porphyrin unit, and an electron acceptor moiety, such as a fullerene compound, which are covalently bonded to each other so as to form a charge-transfer dyad.

A photovoltaic device according to the invention therefore comprises
an anode;
a cathode spaced apart from the anode; and
at least one subcell disposed between the anode and the cathode, said subcell comprising a charge-transfer dyad with a light absorbing electron donor moiety and an electron acceptor moiety, which are covalently linked to each other in a non-flexible configuration and oriented such that each subcell is capable of performing primary photo-induced vectorial electron transfer between the donor and acceptor moieties in the direction from the anode to cathode, which is the natural function direction of the cell.

The subcell is preferably fitted adjacent to a light absorbing polymer, in particular, it is functionally arranged between a light absorbing polymer layer and an electron transfer layer.

The present invention also gives rise to a method of manufacturing a photovoltaic device, which method comprises the steps of providing a first electrode layer, providing a second electrode layer spaced apart from the first electrode layer and disposing a charge-transfer dyad between the anode and the cathode, the charge-transfer dyad comprising a light absorbing electron donor moiety and an electron acceptor moiety, which are covalently linked to each other and orientated as explained above.

According to a preferred embodiment, the method comprises the steps of
a) providing a substrate, such as a sheet of glass or similar inert, preferably transparent material;
b) depositing on the substrate a first electrode layer, comprising for example an indium/tin oxide (ITO), which is capable of forming the anode of the photovoltaic device;
c) depositing a hole transfer layer;
d) depositing a light absorbing layer;
e) depositing on the light absorbing layer a charge-transfer dyad layer using the Langmuir-Blodgett technique;
f) optionally repeating step e), or repeating steps d) and e) or repeating steps c) to e) to provide a plurality of charge-transfer dyad layers optionally deposited on hole transfer layer(s) and light absorbing layer(s);
g) depositing on the top charge-transfer dyad layer an electron transfer layer; and
h) providing a second electrode layer on the electron transfer layer, said layer comprising for example a metal and being capable of forming the cathode of the photovoltaic device.

The present method for producing electricity from light comprises the steps of contacting with light a photovoltaic device comprising at least one light absorbing layer and, adjacent thereto, at least one subcell comprising a charge-transfer dyad with a light absorbing electron donor moiety and an electron acceptor moiety, which are covalently linked to each other in a non-flexible configuration and oriented such that each subcell is capable of performing primary photo-induced vectorial electron transfer between the donor and acceptor moieties in the direction from the anode to cathode, and recovering electricity from the device.

Considerable advantages are obtained by means of the invention. Thus, the structure of the donor-acceptor molecule is highly symmetric increasing the intramolecular electron transfer probability to 100% as demonstrated in liquid phase experiments. This is achieved by linking the donor and acceptor moieties to each other covalently by two linkers, the length of which can be varied.

The primary excitation of the solar cell can take place either by the absorption of the light by the porphyrin-fullerene dyad or, preferably by the absorption of an adjacent photoactive polymer (or oligomer) film, which then transfers the excitation energy to the porphyrin moiety. This phenomenon is highly efficient because the horizontal orientation of the porphyrin unit with respect to the energy donating polymer film. The light absorbing polymer film increases the absorption of the cell and, thus, utilizes the incident light intensity efficiently.

Next, the invention will be examined more closely with the aid of a detailed description and a number of working examples.

### BRIEF DESCRIPTION OF THE DRAWINGS

FIG. 1. Examples of dyad molecules containing donor (porphyrin) and acceptor (fullerene) moieties linked to each other by two molecular chains. The polar hydroxyl groups in the porphyrin end (for DHD6ee) and fullerene end (for TBD6he and for TBD4he) make the formation of Langmuir-Blodgett films possible.

FIG. 2. The surface pressure-molecular area isoterms for Langmuir films at different DHD6ee concentrations (mol-%) in octadecylamine (ODA) matrix.

FIG. 3. Absorption spectra of 2-10 layers of 10 mol-% DHD6ee film in ODA matrix. In insert the absorptions at 435 nm and 520 nm as a function of number of layers.

FIG. 4. Absorption spectra of 1-13 layers of 10 mol-% TBDH4he film in ODA matrix. In insert the absorptions at 428 nm as a function of number of layers.

FIG. 5. The TRMDCM method for measuring the photo voltages created in tested photo cell (Active layers). Number of ODA films in insulating layers is 10-12.

FIG. 6. Two arrangements for orientation of the active layers in the TRMDCM method. By depositing a Langmuir film of DHD6ee by drawing the substrate containing a glass plate covered by an ITO layer and insulating ODA layers from down to up the dyad molecules are oriented transfer the electrons to direction from ITO to Al electrode. A triad system (on the right is obtained by depositing first a PH7T layer on insulating ODA layers and then a dyad layer from down to up. Then direction of the electron transfer can changed to opposite by depositing the PHT and dyad films from down to up and up to down, respectively.

FIG. 7. Photovoltage signals for 10 mol-% DHD6ee film in the ODA matrix deposited in two different directions: deposition yielding a positive signal is up to down and that for the negative signal is down to up.

FIG. 8. The phenylvinylthiophene (PVT) compounds (oligomers and a polymer) used as energy transfer layer for exciting the porphyrin moiety in the dyad.

FIG. 8a. The absorption spectra of 100% PVT3 and 40 mol-% PVT3 in an ODA matrix.

FIG. 9. The photovoltage signals for 40 mol-% PVT3 in ODA with opposite depositions of the Langmuir films. The negative signal in both cases demonstrates the direction of the electron transfer to be the same.

FIG. 10. Absorption (left) and excitation spectra (right) of 10 mol-% DHD6ee (a diad system), 40 mol-% PVT3, and triad system containing a film of 10 mol-% DHD6ee in ODA deposited from down to up on 40 mol-% PVT3 film. The emission att the wavelength of 720 nm, in the excitation spectra is mainly due to emission of the porphyrin moiety. The high intensity of the excitation spectrum (compared to the intensity of the PVT3 film) indicates the energy transfer from PVT3 to porphyrin.

FIG. 11. The photo voltage signals for three systems: ITO|DHD6ee|Al (solid line), ITO|40% PVT3|Al (dashed line), and ITO|PVT3|DHD6ee|Al (dashed-dotted line).

FIG. 12. Polyhexylthiophene (PHT) polymer, a hole transfer material, and PPG polymer, a electron transfer material.

FIG. 13. Photo voltage signals for PHT-PVT3 bilayer samples: ITO|ODA|PVT3|PHT|ODA|Al (dashed line) and ITO|ODA|PHT|PVT3|ODA|Al (solid line). The excitation wavelength was 410 nm. Because PVT3 always shows a negative signal (and electron transfer from ITO to Al) the positive signal indicates an electron transfer direction from Al to ITO and thus the interlayer electron transfer from PHT to PVT3. The negative signal, with higher intensity shows also the electron transfer from PHT to PVT3.

FIG. 14. The photovoltage signals for a ITO|ODA|PHT|DHD6ee|ODA|Al system compared to that of the ITO|ODA|DHD6ee|ODA|Al system in two different time domains.

FIG. 15. The photo voltage signal intensities as a function of excitation light intensity for ITO|ODA|PHT|DHD6ee|ODA|Al and ITO|ODA|PHT|ZnDHD6ee|ODA|Al indicating of about 4 times increase of the intensity.

FIG. 16. The photovoltage signal intensities for systems ITO|ZnDHD6ee|Al, ITO|40 mol-% PVT3|ZnDHD6ee|Al, ITO60 mol-% PHT|ZnDHD6ee|Al, and ITO|PHT|100 mol-% PVT3|ZnDHD6ee|Al as a function of the excitation light intensity.

FIG. 17. Schematic presentation of solar cell Example 1

FIG. 18. Schematic presentation of solar cell in Example 2

FIG. 19. Schematic presentation of solar cell in Example 3

FIG. 20. Schematic presentation of solar cell in Example 4

### DETAILED DESCRIPTION OF THE INVENTION

The present invention provides organic photovoltaic cells comprising different molecular layers, each having own specific function, which together form an effective device.

One of the layers comprises the porphyrin-fullerene dyad, in which the redox- and photoactive components are brought together by two separate linkers and a nearly symmetric complex geometry with π-stack sandwich-like structure is achieved.

In the course of the work leading up to the present invention, a series of dyads, bearing different linkers, was synthesized to fine-tune the inter-chromophore interactions and their impacts on the physical and chemical properties. Absorption spectroscopy emerged as a convenient means to register the inter-chromophore interactions: the spectra of the chromophores ground state absorptions show appreciable perturbations and, more importantly, an additional absorption feature is discernable in the near infrared region. Similarly, the emission spectra have a character typical for intermolecular exciplex. These new spectral features (i.e., absorption and emission) were attributed to a new electronic state, namely, an intermolecular preformed exciplex, featuring a common molecular orbital with a partial charge transfer (CT) character. Photodynamics of the dyads were studied in the femto- and picosecond time domains using the emission up-conversion and absorption pump-probe techniques.

Exciplex formation exerts a strong impact on the electron transfer (ET) features of the resulting porphyrin-fullerene ensembles. Arguably its low energy might be the reason for the inability of the Zn porphyrin - fullerene dyads to undergo CS in non-polar media. In the exciplex the two chromophores form a common molecular orbital and its appearance depends on the mutual alignment and ordering of the corresponding porphyrin and fullerene moieties. In the most distinct exciplex manifestation, compact sandwich-like arrangements are inferred and it seems that this type of organization is further enforced by strong π-π interactions between the planar porphyrin and the spherical fullerene moieties.

Intriguing incentives to organize porphyrin/fullerene hybrids can be borrowed from crystal structures of porphyrin/fullerene mixtures. The crystal packing, found for example in the X-ray crystal structure of a fulleropyrrolidine/free base tetraphenylporphyrin hybrid, gives way to a clear picture on the disposition of both moieties. An appreciable intermolecular interaction evolves from an unexpectedly close approach between C₆₀ and porphyrin. The distances of the closest C₆₀ C-atoms to the mean plane of the inner core of porphyrin are quite short, with values of 2.78 Å and 2.79 Å. This led to the formulation of a new porphyrin/fullerene relationship, that is, augmentation of the usual π-π association by electron donor-electron acceptor interactions. Following the remarkable results of the initial work on a covalently linked dyad, this aspect was systematically explored in a series of porphyrin/fullerene cocrystallates, where porphyrins and fullerenes were not chemically linked to each other. Various metal species, ranging from Mn, Co, Ni, Cu, Zn to Fe, were chosen. Common to all C₆₀-based cocrystallates is that electron rich areas, i.e. carbon atoms at hexagon-hexagon junctions, lie over the center of the porphyrin ring. As a direct consequence, complexes with unusually short contacts (2.7-3.0 Å), shorter than the ordinary van der Waals contacts (3.0-3.5 Å), are formed. The experimental data, such as ESR, IR, absorption and X-ray photoelectron spectroscopy, fail to indicate noticeable charge transfer features in these porphyrin/fullerene cocrystallates, despite the porphyrins excellent electron donating ability and the electron accepting character of C₆₀.

As will be discussed below, the present invention is based on the use of at least two linkers interconnecting the porphyrins and fullerenes. We have found that by employing merely a single linker, a substantial degree of conformational flexibility in the molecular topology is generated. As a result of such flexibility:
(i) the porphyrin/fullerene organization in the hybrids is rather poorly defined and/or
(ii) the fullerene cannot be brought into a position that centers on top of the porphyrinic macrocycle.

By contrast, when porphyrins and fullerenes are brought together according to the present invention by (at least) two separate linkers, symmetrical dyads with π-stack sandwich structures are achieved. This molecular design opens new possibilities in controlling interchromophore interactions and in fine-tuning the properties of the intramolecular exciplex.

Based on the above, according to a particularly preferred embodiment of the invention, the efficiency of photovoltaic devices is improved by incorporating into the devices a charge transfer dyad, in which the primary excited photoactive molecules, containing the electron donating moiety, a porphyrin unit, and the electron accepting moiety, the fullerene unit, are oriented anisotropically, by applying the Langmuir-Blodgett technology, in one direction so that the photoinduced electron transfer takes always place from the donor to the acceptor moiety. As explained above, this phenomenon creates an intramolecular and, simultaneously, an intralayer potential, which then at the interface of another molecular layer forms a photovoltaic heterojunction supporting the electronic charge transport preferably in the same direction as the primary intramolecular charge transfer. The orientation in the Langmuir films is due to the covalently linked hydrophilic groups attached either to the donor end or the acceptor end of the molecule. This increases the possibilities to orient the molecules as desired.

The described heterojunction is preferably deposited on a substrate, for example, a piece of glass, metal, ceramic polymer or any mechanically suitable material. For solar cells it is preferred that the substrate is transparent, such as glass. Generally, if the substrate material is not conducting, a conducting electrode layer must be applied to serve as one contact to the charge-transfer layer. Possible conducting layers for said contact are metal layers, conducting layers made from mixed oxides (in particular transparent oxides, such as indium/tin oxide) and conducting polymer layers (such as polyaniline or conducting polyblends of polyaniline).

In following, the various molecular layers of the organic photocells and their functions will be described in further detail with reference to the attached drawings.

### 1. Donor-Acceptor Dyads

It is essential that the primary electron transfer, initiating the function of the photovoltaic device, takes place in the direction of the current in the photocell, and that this process is efficient. The efficiency of the electron transfer between the primary acceptor and the donor can be increasingly controlled by the distance and the mutual arrangement of the donor and the acceptor and by their redox potential difference. By studies of the mechanisms and kinetics of the photo-induced electron transfer in several phytochlorin-fullerene and porphyrin-fullerene dyads in solutions, the mechanisms and the factors controlling the effectiveness have been solved (N. V. Tkachenko, L. Rantala, A. Y. Tauber, J. Helaja, P. H. Hynninen, and H. Lemmetyinen, Photoinduced Electron Transfer in Phytochlorin-[60]fullerene Dyads, J. Am. Chem. Soc., 121, 1999, 3978-9387, Tero J. Kesti, Nikolai V. Tkachenko, Visa Vehmanen, Hiroko Yamada, Hiroshi Imahori, Shunichi Fukuzumi, and Helge Lemmetyinen, Exciplex intermediates in photoinduced electron transfer of porphyrin-fullerene dyads, J. Am. Chem. Soc., 124, 2002, 8067-8077).

The mutual distance, arrangement, and self-assembling is best controlled, especially in solid structures, by symmetric structures containing two linkers between the acceptor and donor.

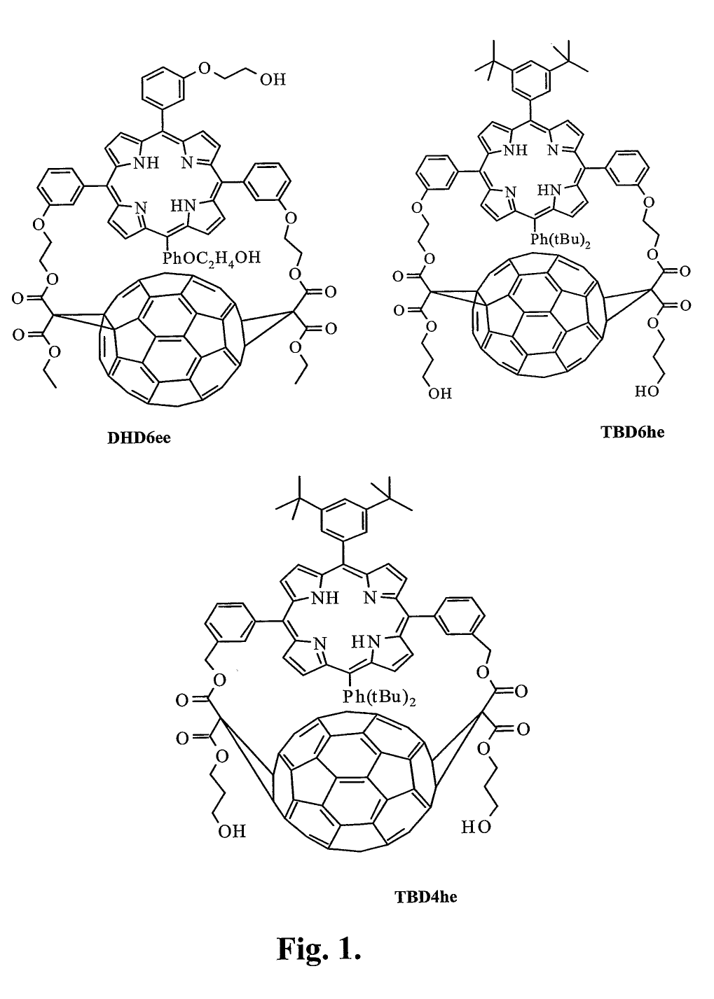

FIG. 1 shows, as an example, three embodiments of dyads according to the invention, comprising an electron donor unit, porphyrin, and an electron acceptor unit, fullerene. The methods of synthesis fof dyads used in present are described in details in Efimov, A.; Vainiotalo, P.; Tkachenko, N. V.; Lemmetyinen, H. Journal of Porphyrins and Phthalocyanines, 2003, 7(9), 610-616. The synthesis can be outlined simply by few steps: first the condensation of porphyrin macrocycle. After this, needed functional groups are attached to tetra-phenyl porphyrin to enable connection to fullerene moiety. Finally, fullerene is attached by using the modified Bingel reaction. The molecular chains interlinking the porphyrin and the fullerene units are comprised of chains having 4 to 10, preferably 4 to 6 atoms between the donor and acceptor moieties.

The hydrocarbon chains of the linkers can optionally exhibit irregularities in the chain. Such irregularities can comprise heteroatoms or double bonds. The heteroatoms are preferably selected from oxygen, sulphur and nitrogen. The hydrocarbon chains are preferably linear and they can contain substituent groups, such as hydroxyl, carboxy, oxy, nitro, amide, thio and imide groups.

It would be preferable to have plain hydrocarbon chains as linking bridges between porphyrin and fullerene moieties. But it is far easier task to compile the linkers from such a functional groups as hydroxyl and carboxyl groups. Thus, instead of having CH-chain one will obtain chain of ester and ether groups as linking chains.

The vectorial electron transfer reactions in the dyads have been studied in details in different solutions by applying femto second spectroscopic methods. It has been found, that reactions takes place in several steps, viz:

| | | |
|---|---|---|
| 1. | Excitation of the porphyrin: PF + hv → P * F | rate: I_{A} |
| 2. | Intramolecular excimer formation: P * F → (PF)* | rate: kₚₓ |
| 3. | Intramolecular electron transfer: (PF)* → P⁺F⁻ | rate: kₓᵢ |
| 4. | Ion recombination: P⁺F⁻ → PF | rate: k_{ig} |

The determined rate constants for compound DHD6ee are presented in Table 1 (Vladimir Chucharev, Nikolai V. Tkachenko, Alexander Efimov, Dirk M. Guldi, Andreas Hirsch, Michael Scheloske, and Helge Lemmetyinen, Tuning the ground and excited states interchromophore interactions in porphyrin-fullerene π-stacs, J. Phys. Chem. A, 2004, in press) and show that processes are extremely fast. The quantum yield for the charge transfer state, P⁺F⁻, formation was estimated to be close unit, but the charge recombination took place also in time less than 100 pico second.

TABLE 1

| Compound and | | | |
|---|---|---|---|
| Environment | kₚₓ/10⁹ s⁻¹ | kₓᵢ/10⁹ s⁻¹ | k_{ig}/10⁹ s⁻¹ |
| DHD6ee/in polar | 10 000 | 100 | 2.6 |
| solution | | | |
| DHD6ee/in nonpolar | 6 000 | — | — |
| solution | | | |
| ZnDHD6ee/in polar | 23 000 | 770 | 16 |
| solution | | | |
| ZnDHD6ee/in | 10 000 | — | — |
| nonpolar solution | | | |

Above, fullerene (C₆₀) is used. For the sake of completeness it should be pointed out that it is also possible to use C₆₀ derivatives containing different substituent groups as well as a whole series of fullerenes from C₄₀ to C₁₀₀.

The light absorbing electron donor moiety is preferably a porphyrin unit or a phthalocyanine unit, i.e. a compounds comprising a tetrapyrrolic residues.

Mn, Co, Ni, Cu, Zn and Fe analogues of the porphyrins and phtalocyanines are also included in the invention.

### 2. Langmuir-Blodgett Films of the Dyads

The vectorial electron transfer discussed above and demonstrated in solutions was utilized in solid structures by employing molecules containing polar ends, essential for solid film preparation, either in the porphyrin or fullerene end of the dyad (FIG. 1).

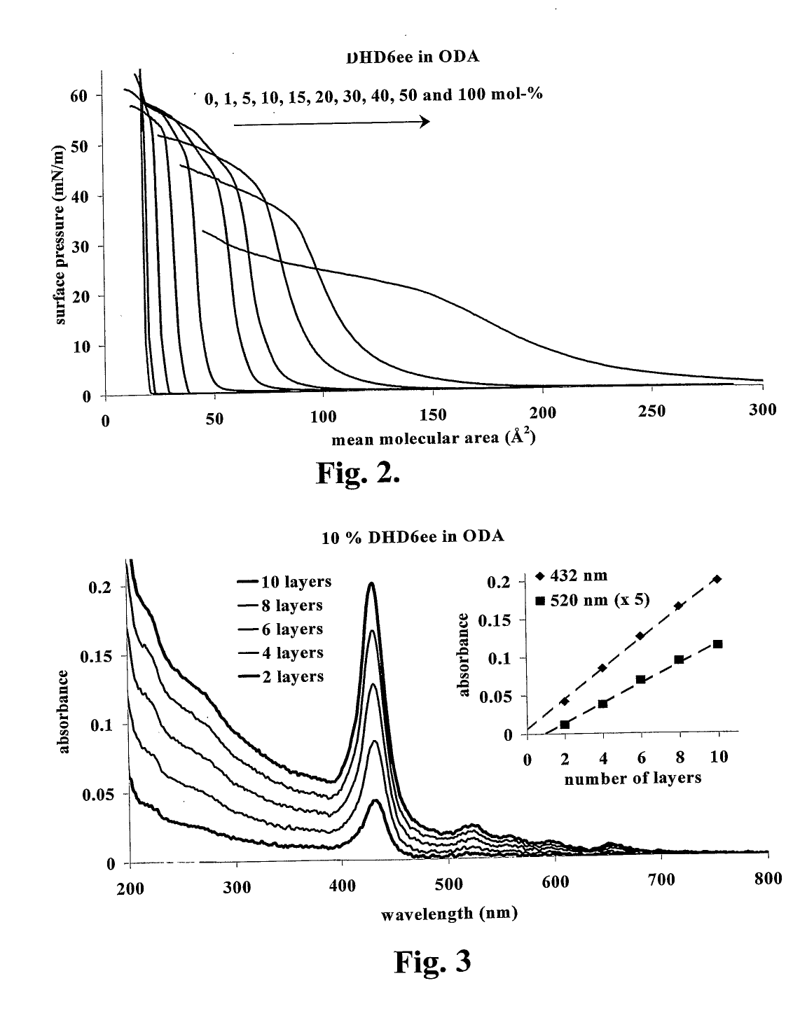

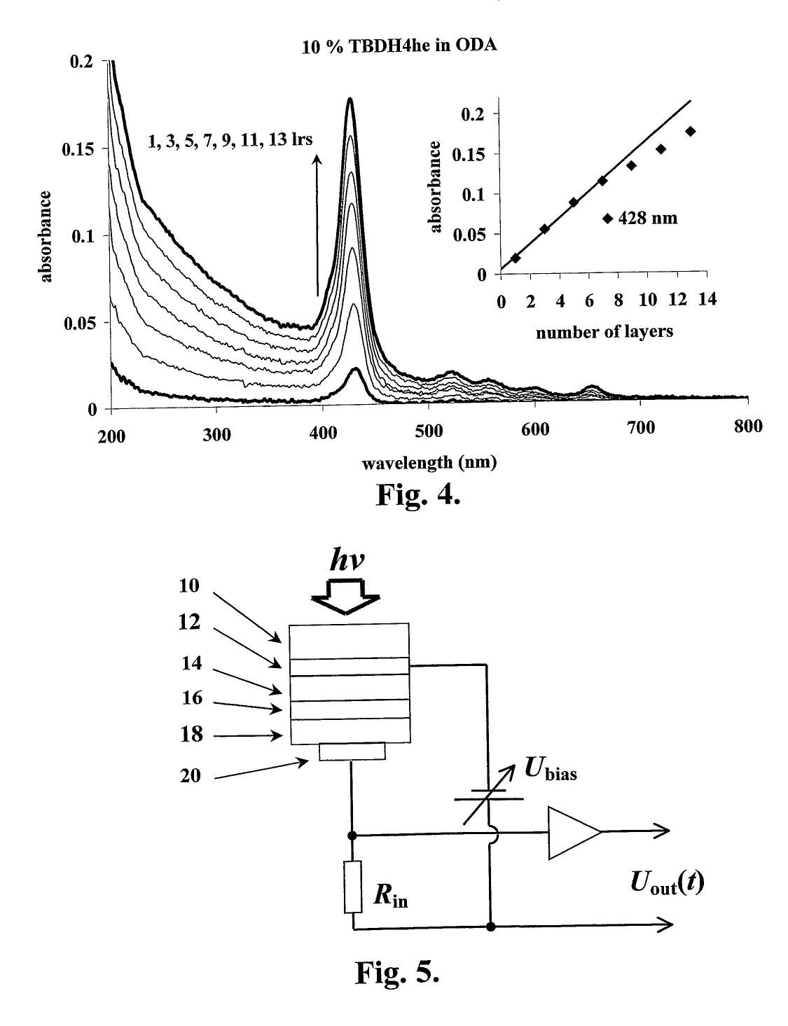

Due to the two polar tails, the hydroxyethoxy groups in the porphyrin end (for DHD6ee) and the hydroxypropylcarboxylate groups in the fullerene end (for TBD6he and TBD4he), the dyad compounds form high quality Langmuir films (FIG. 2), which can be deposited as Langmuir-Blodgett films on a solid substrate, e.g. on glass covered by an ITO electrode (FIG. 3 and FIG. 4). The polar ends orientate the hydrophobic donor and acceptor molecules as desired. As a result, orientated Langmuir films are obtained.

Preferably the polar ends comprise groups containing electronegative atoms, such as oxygen or nitrogen. Examples of polar groups are hydroxyl groups, carboxy acids, amine groups etc. Non-polar (hydrophobic) end groups are typically hydrocarbon chains, such as linear or branched alkyl groups. When the polar side of one dyad is fitted against the non-polar end of another, the molecules and the dyads are arranged in a stacked fashion.

The deposition technique of the donor-acceptor molecules should allow for anisotropical orientation of the molecules such that they will provide photoinduced electron transfer in the direction from the donor to the acceptor moiety. The photovoltaic heterojunction thereby supports the electronic charge transport in the same direction as the primary intramolecular charge transfer.

It is particularly preferred to use the Langmuir-Blodgett technique for orienting the donor-acceptor molecules where the primary electron transfer takes place.

The thickness of one layer is typically about 2 nm and that of the whole PV cell from 6 to 120 nm.

### 3. Photo-Voltage Measurements for Different Type of Films.

The photovoltage measurements of dyad monolayers and different multi-layer structures were measured by using a Time Resolved Maxwell Displacement Charge Method (TRMDCM), described in FIG. 5 (Ikonen, M., Sharanov, A., Tkachenko, N, Lemmetyinen, H., Adv. Mater. Opt. Electron. 1993, 2, 211).

In FIG. 5, the reference numeral 10 stands for the glass substrate, 12 for the anode (the ITO electrode), 14 and 18 refer to ODA layers, 16 to a layers of the active materials and 20 to the cathode (Al electrode).

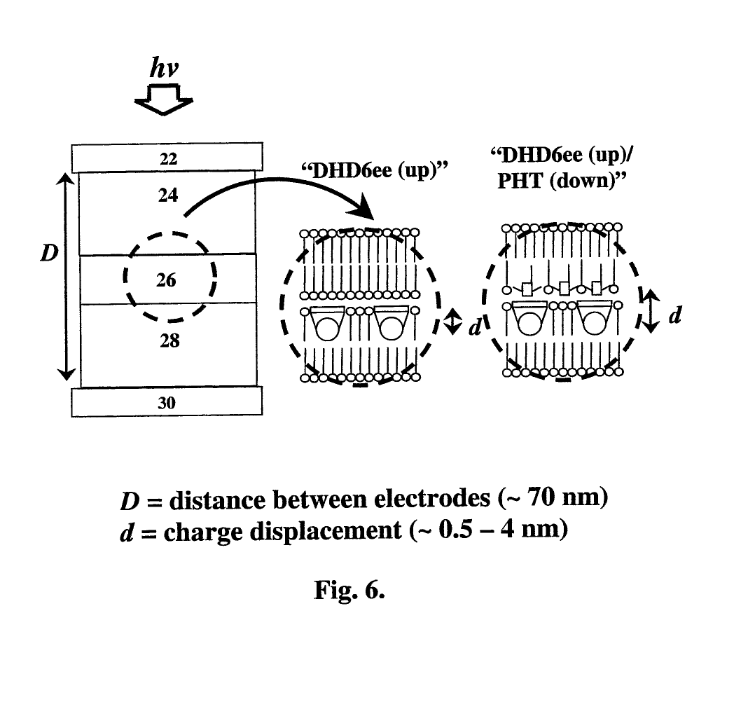

Photovoltage response amplitudes were measured as a function of excitation energy density. The experiments were performed by using either InGa liquid metal alloy drop-electrodes or Al-electrodes. The adjustments of the films, all prepared by applying the Langmuir-Blodgett technique, are shown in FIG. 6. The TRMDCM method can be used for fast detection of vectorial electron transfer for different types of molecular films avoiding direct contacts between the solid electrodes and photo and electro active materials.

In FIG. 6, reference numeral 22 represents the anode (ITO), 24 and 28 represent insulating layers and 26 the active layers. Reference numeral 30 represents the cathode.

### 3.1. Photovoltage Signals for Dyad Films.

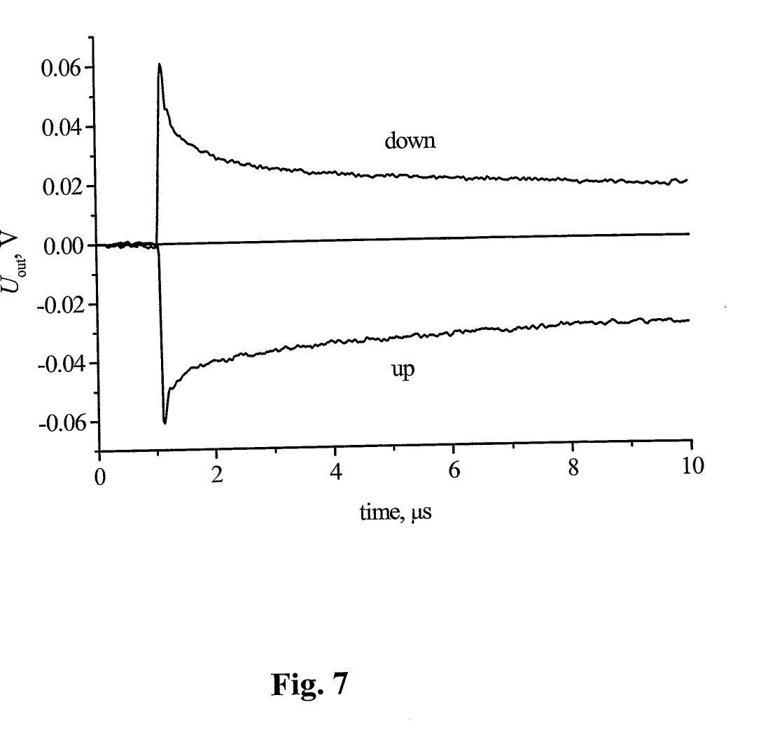

All dyad molecules showed symmetrical photo-response signals with polarity depending on the deposition direction indicating that vectorial electron transfer takes place in the films (FIG. 7). It is essential to notice, that the signals (being not single exponential) have life-times on the order of tens of microseconds, whereas in solutions the charge recombination takes place in time less than 100 picoseconds. This increased lifetime of the charge transfer state, taking place already in pure dyad films, indicates that the electron-hole pairs in the films are separated, a property necessary for a photocell.

### 3.2. PVT-Oligomer Films and Energy Transfer to Dyads.

The primary electronic excitation can be achieved, in addition to the excitation of the donor moiety in the dyad, by irradiating a specific light absorbing layer deposited adjacent to the to the donor moiety. After excitation of this layer, the excitation energy is transferred to the donor moiety in the dyad, which is thus excited. By using suitable molecular material for absorbing layer preparations, the spectral area of the absorption is broadened thus improving the total efficiency of the photocell.

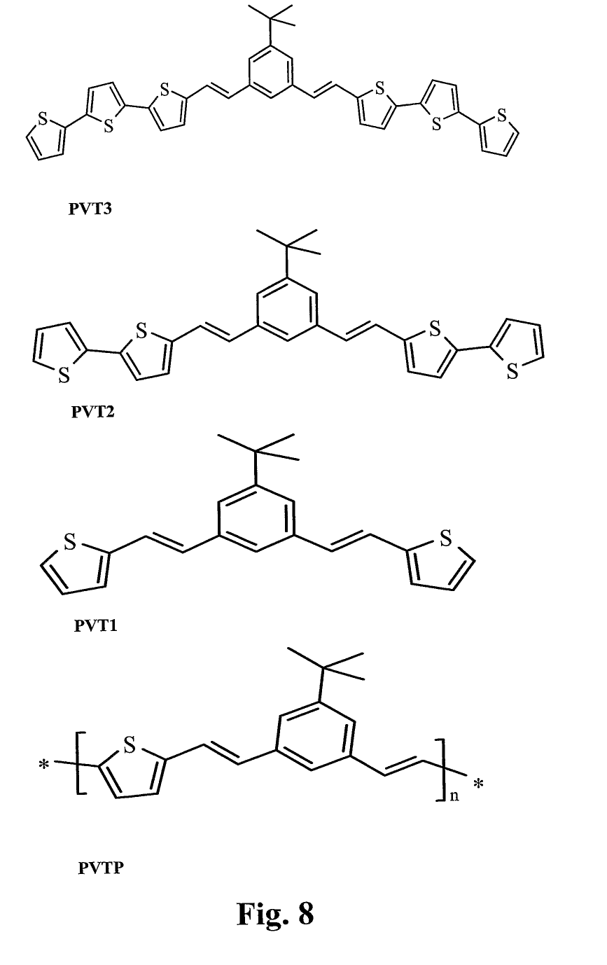

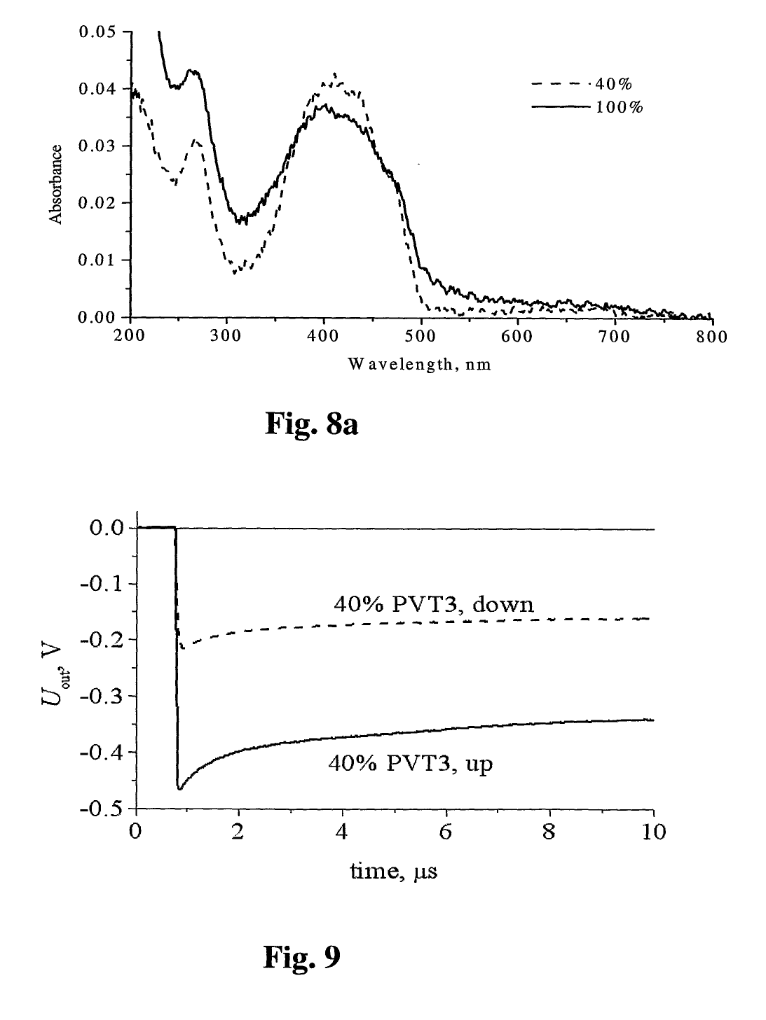

A series of PVT-oligomers was synthesized (FIG. 8) and their photo-electrical properties were studied (FIG. 8a and FIG. 9). When the samples were deposited, by applying the Langmuir-Blodgett techniques, onto glass covered with semitransparent ITO semiconductor, and studied with the TRMDC method, they showed a negative photo-electrical signal, independent of the deposition direction, indicating that the direction of the electron transfer was from ITO to Al-electrode (FIG. 9). Due to this orientation of the oligomers also other film preparation methods than the Langmuir-Blodgett technique can be used. Examples of such techniques are: vacuum deposition, spin coating, organic vapor-phase deposition, inkjet printing and other methods known in the art.

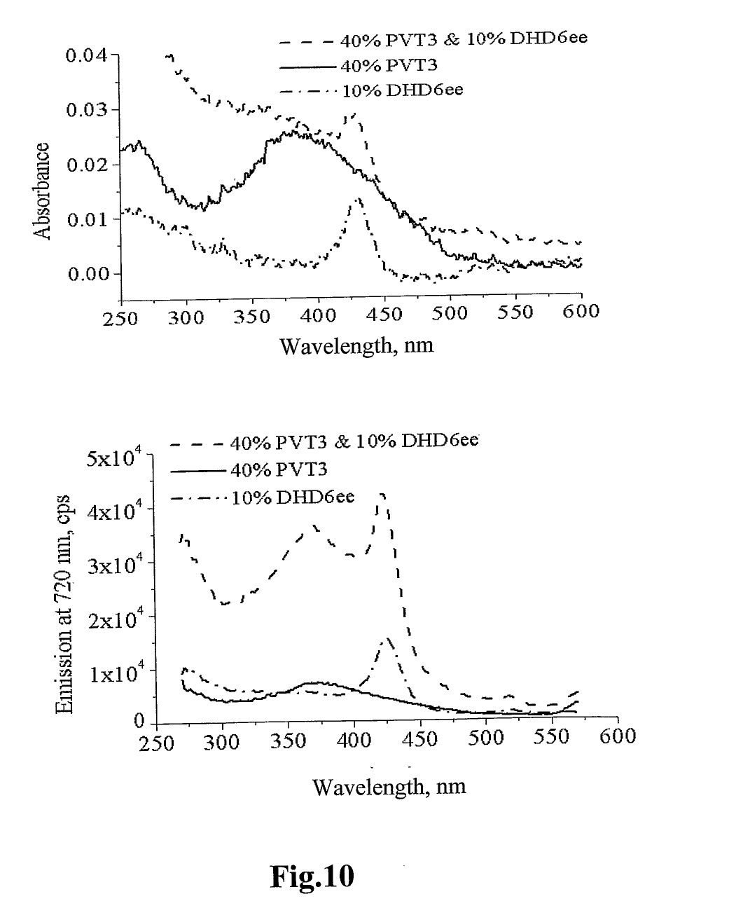

When on dyad film was deposited on the PVT3-film and the fluorescence properties were studied, the results showed, that PVT3, after absorbing light, transfer the excitation energy to the porphyrin moiety in the dyad. This can easily be seen by comparing the absorption and excitation spectra (when monitored at the wavelength of the porphyrin emission) of the three different systems, namely PVT3, dyad DHD6ee, and PVT3+DHD6ee, as shown in FIG. 10.

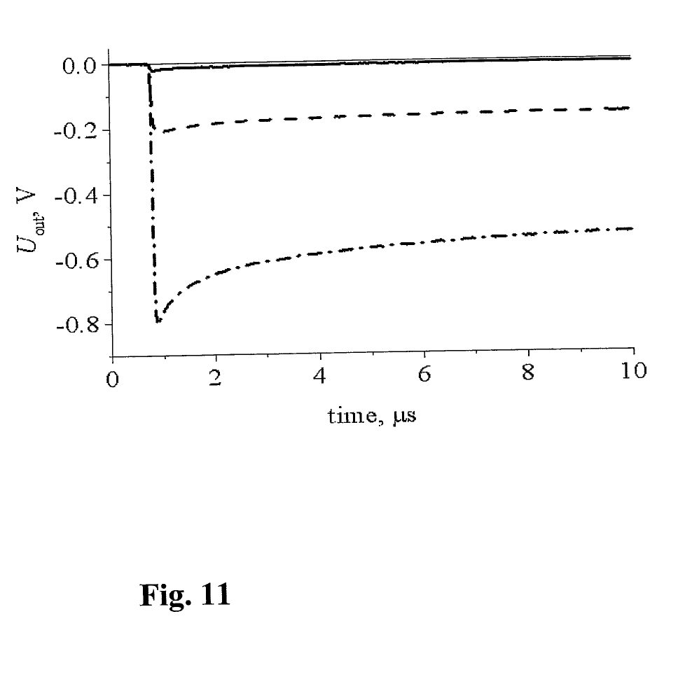

The influence of the energy transfer from PVT3 to porphyrin can be studied when a film structure ITO|PVT3|DHD6ee|Al was studied. Compared to the system ITO|DHD6ee|Al the signal intensity increased approximately 40 times (FIG. 11).

### 3.3. Photo-Electricity in PVT3-PHT-Films.

Many p-type organic semiconductors can be used as hole transfer materials. Depending on the purpose and the method of the layer preparation, the following polymeric compounds and their alkyl derivatives are suitable for the present use: polyacetylenes, polyparaphenylenes, polypyrroles, polythiophenes, polyparaphenyl vinylenes, polycabazoles, polyheptadiynes, polyquinolines, and polyanilines. Basically, other hole transporting materials can also be used, including aromatic tertiary amine compounds, such as N,N′-bis(3-methylphenyl)-N,N′-bisphenyl-benzidine (TPD) and N,N′-di(naphthalene-1-yl)-N,N′-diphenyl-benzidine (NPD), hydrazone compounds, quin-acridone compounds and styrylamine compounds.

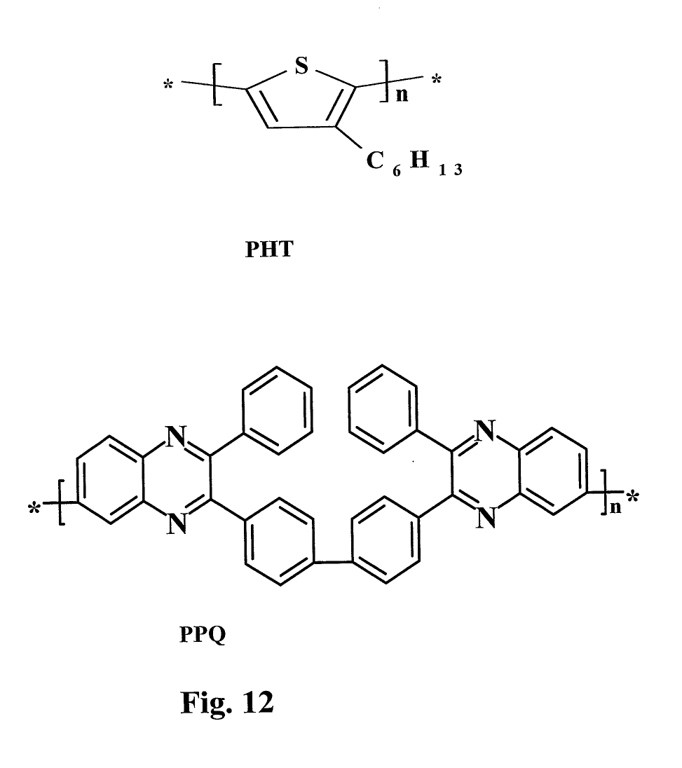

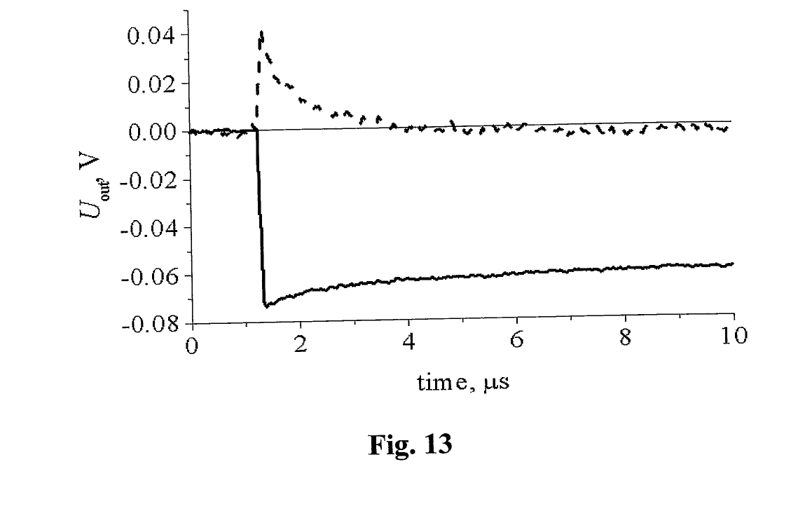

The spin coating method is suitable in most cases, but Langmuir-Blodgett techniques can be applied only for compounds containing alkyl chains, which are sufficiently long. In the present case, polyhexylthiophene, PHT, (FIG. 12) is used as a basic material, because it can form relatively good quality Langmuir-Blodgett-films. The photo-electrical signals for two types of PHT-PVT3-films were examined in order to study the electron transfer from the p-type semiconductor to PVT3. The film structures ITO|PVT3|PHT|Al and ITO|PHT|PVT3|Al were constructed. In the former case, positive and in the later case negative signals were obtained (FIG. 13) indicating in both cases the charge transfer from PHT to PVT, which could act as an n-type semiconductor.

### 3.4. Photo-Electricity in the PHT-dyad-films.

In order to utilize the primary electron transfer in a dyad molecule the positive and negative charges have to be separated from each other. This can be achieved by a secondary electron transfer from a secondary electron donor to a porphyrin cation radical formed in the primary electron transfer of the dyad. Also an electron transfer from the fullerene anion to a secondary electron acceptor must take place before a recombination of the CS state in dyad monolayer.

The fast back-electron transfer, or charge recombination, of dyad molecules can be delayed or even avoided in triad systems, where the primary donor ejects the electron to an acceptor and receives another from the secondary donor adjacent to it. The simplest system of this kind is a semi-conducting conjugated polymer film of PHT on which a dyad layer is deposited by applying the Langmuir-Blodgett techniques. Thus, a structure containing ITO|PHT|dyad|Al is obtained with the porphyrin moiety adjacent to PHT. A vectorial (anisotropic) electron transfer is created in this kind of layered films deposited between the electrodes.

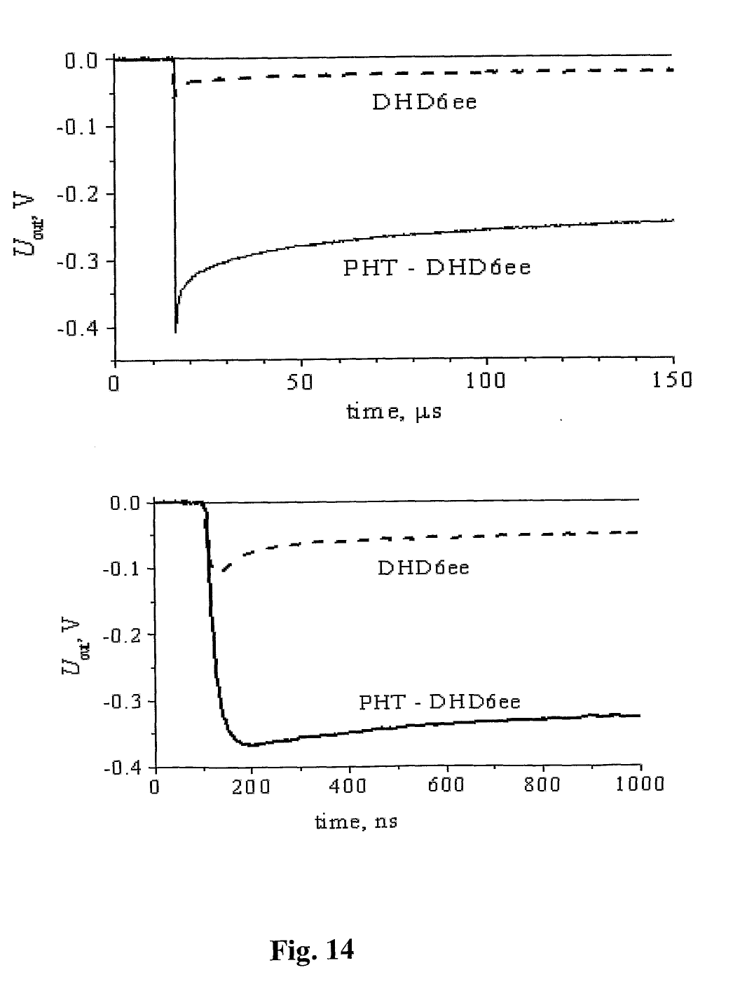

The main effects of the PHT layer can be seen in FIG. 14. The PHT layer causes an almost 4-fold increase in the response amplitude (FIG. 14 left). In addition, the CS state is longer living (FIG. 14 right). Because the amplitude of the photovoltage response signal is proportional to the charge displacement distance perpendicular to the plane of electrode, a higher signal indicates that the CS state has longer charge separation. The longer living response signal is an indicator of the longer distance between recombining charges, i.e. the electron in the fullerene and the positive hole in the PHT layer. Thus, the primary charge separation in the DHD6ee dyad was extended by the secondary electron transfer from the polyhexylthiophene film to the porphyrin cation radical.

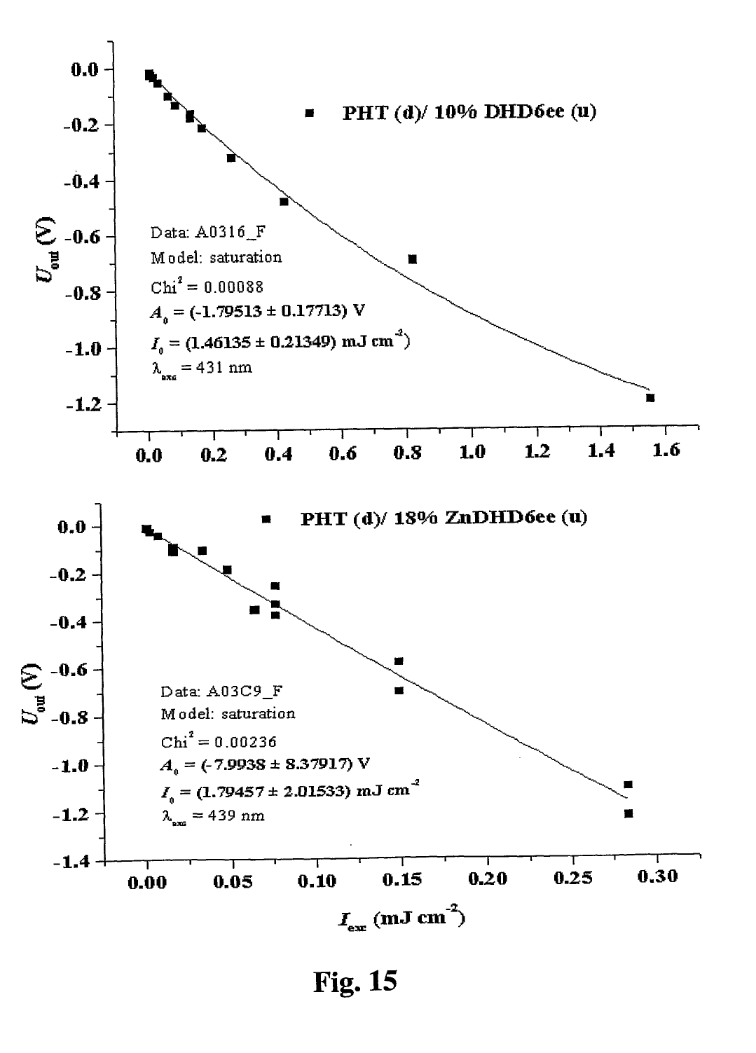

The photovoltage amplitude intensities were even further improved by using the Zn-porphyrin moieties in the dyads. Thus, when the signals intensities were measured as a function of the excitation light densities for the cell systems ITO|PHT|DHD6ee|Al and ITO|PHT|ZnDHD6ee|Al, the intensities were increased by a factor of about four when the Zn-derivatives of the dyads were used, as can be seen from the slopes of the voltage-excitation density lines (FIG. 15).

3.5. Photo-Electricity in the PHT-PVT3-dyad-films.

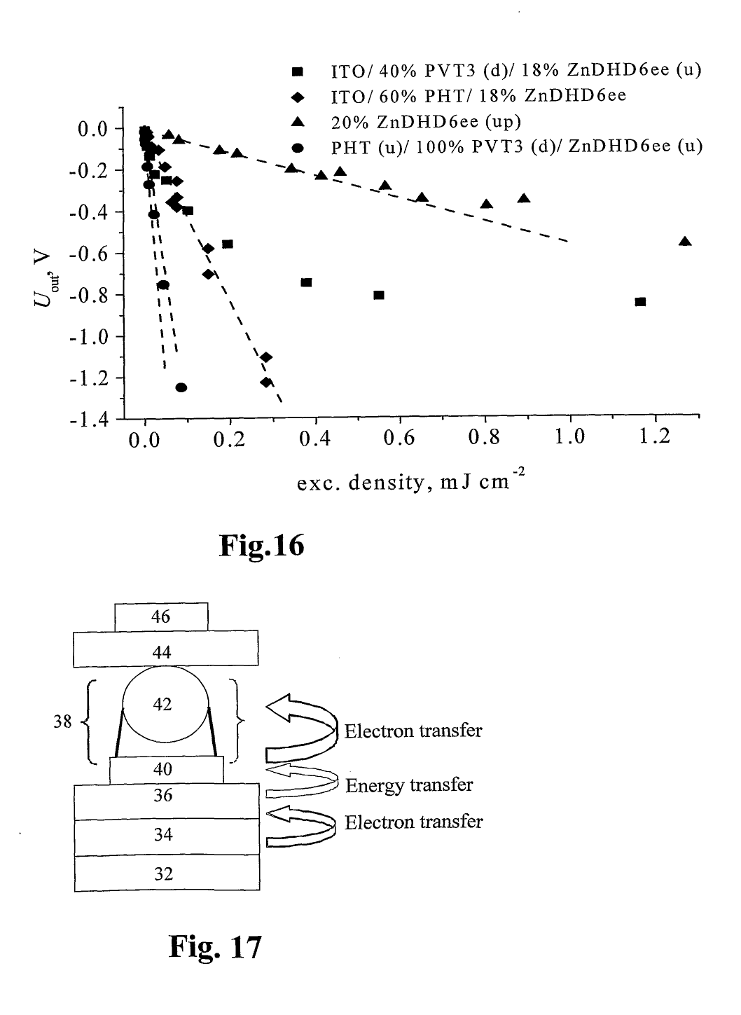

Finally, the signal intensities of different types of cell structures are compared with that being composed in a sequence of ITO|PTF|PVT3|DHD6ee|ITO. The result is shown in FIG. 16, where the increasing negative slopes of the voltage-excitation density lines are presented for the systems

ITO|ZnDHD6ee|Al,

ITO|40 mol-% PVT3|ZnDHD6ee|Al,

ITO|60 mol-% PHT|ZnDHD6ee|Al, and

ITO|PHT|100 mol-% PVT3|ZnDHD6ee|Al.

The slopes for the different cell systems are presented in Table 2, together with the estimated photovoltage quantum efficiencies.

TABLE 2

| sample | Slope | QY |
|---|---|---|
| ZnDHD6ee | −0.556 | 0.0034 |
| PHT-ZnDHD6ee | −4.11 | 0.017 |
| PVT3-ZnDHD6ee | −14.5 | 0.025 |
| PHT-PVT3-ZnDHD6ee | −24.9 | 0.029 |

### 3.6. The Function of the Electron Transfer Layer (ETL).

The active organic layers, performing the photo induced electron transfer from the hole transfer layer (HTL) to the outermost fullerene film of the PV cell, are finally covered by electron transfer layer/s (ETL) in order to transmit the electrons to the cathode. As ETL a multilayered poly(p-phenylene-2,3′-bis(3,2′-diphenyl)-quinoxaline-7-7′-diyl) (PPG, FIG. 12) or conductive gold nanoparticle layers.

### Abbreviations

In the present specification and claims, the following abbreviations are used:
DHD6ee: di-hydroxyl porphyrin double-linked (6 atoms in bridge) fullerene ethyl ester
ZnDHD6ee: Zinc complex of DHD6ee
TBD6he: di tert-butyl porphyrin double-linked (6 atoms in bridge) fullerene hydroxyl ester
TBD4he: di tert-butyl porphyrin double-linked (4 atoms in bridge) fullerene hydroxyl ester
ODA: n-octadecylamine
TRMDCM: Time Resolved Maxwell Displacement Charge Method
ITO: indiumtin oxide
PHT: polyhexylthiophene (poly-(3-hexylthiophene-2,5-diyl))
PVT: phenylvinylthiophene
PVT3: phenylvinyltrithiophene
PPQ: poly(p-phenylene-2,3′-bis(3,2′-diphenyl)-quinoxaline-7-7′-diyl)

### EXAMPLES

Herein, fabrication of actual devices for this invention will be described. The devices with different configurations (FIG. 17-20) have different sequences of active layers. The preparation of each sample will be described in the examples below.

### Example 1

A photovoltaic device shown in FIG. 17 was manufactured as follows:

First, a glass substrate (not shown in the drawings), precoated with indium/tin oxide (ITO) 32, or a similar light transparent conductive oxide, was cleaned by immersing it into cleaning solutions (first into acetone and then into chloroform). Just prior to use, the substrate was plasma-etched in nitrogen atmosphere. The size of the substrate was 12×35×1 mm. For the Langmuir-Blodgett (LB)-technique, 0.6 mM phosphate buffer was used as a subphase at temperature 20° C.

Next, a hole transfer layer (HTL) 34 was deposited onto clean substrate by LB-technique or by spin coating method. A p-type semiconductor, regioregular poly(3-hexylthiophene-2,5-diyl) (PHT) was used as an example. A PHT multilayer LB film was prepared from a mixture of polymer and matrix, n-octadecylamine (ODA), in molar ratios from 6:4 per PHT monomer unit to 100 mol-% PHT. For spreading onto water surface, molecules were dissolved in chloroform with a total concentration of 0.8 mM (for ODA and PHT monomer unit). LB deposition was made at a surface pressure of 20 mN m⁻¹ with substrate dipping speed 7 and 4 mm min⁻¹ for air-to-water and water-to-air depositions, respectively. LB deposition was started onto the pure substrate with water-to-air direction. Drying time for the first LB layer was 40 min and for the following layers 15 min. Spin-coating was made from chlorobenzene solution with PHT concentration of 5 mg per ml with rotating speed 1500 rpm.

Next, a light absorbing layer (LAP) 36 was produced, for example, from PVT3. The PVT3 layer was prepared by means of the LB-technique. The spreading solution was made in chloroform having a total concentration 0.6 mM, with molar ratios from 7:3 of PVT3: ODA to 100 mol-% PVT3. PVT3 deposition was made at a surface pressure of 20 mN m¹ with substrate dipping rate 5 mm min⁻¹ for both deposition directions. Drying time between PVT3 layers was 15 min.

Then, a porphyrin-fullerene dyad layer 38 was deposited by the LB-technique. The dyads used in the example were DHD6ee, TBD4he and TBD6he, and their metalloporphyrin analogues. The dyad was formed by the porphyrin portion 40 and the fullerene compound 42. The fraction of any dyad in the ODA matrix was 20 mol-%. The dyad LB deposition was made at a surface pressure of 15 mN m⁻¹ with a deposition rate of 5 mm min⁻¹ for all dyads in both directions. DHD6ee or its metalloanalogues was used for the device shown in FIG. 17.

In the following step, an electron transfer layer (ETL) 44 was prepared. This layer can consist of a multilayer of poly(p-phenylene-2,3′-bis(3,2′-diphenyl)-quinoxaline-7-7′-diyl) (PPQ) or conductive gold nanoparticles. The PPQ layer was deposited by means of the Langmuir-Schaffer (LS)-method from a 100% PPQ surface film at the air-water interface, using a surface pressure of 5 mN m⁻¹. The multilayer of gold nanoparticles was also prepared by the LS-method. Deposition was done at a surface pressure of 20 mN m⁻¹. The drying time between LS depositions was 15 min.

Finally, a cathode 46 was evaporated on top of multilayer structure. Thermal evaporation of aluminum was done under high vacuum (p<10⁻⁵ mbar) onto masked samples. The evaporation rate was 0.1 to 0.3 nm s⁻¹ and the final electrode thickness was 50 to 60 nm. The overlap area of cathode and anode was approximately 2 by 2 mm.

### Example 2

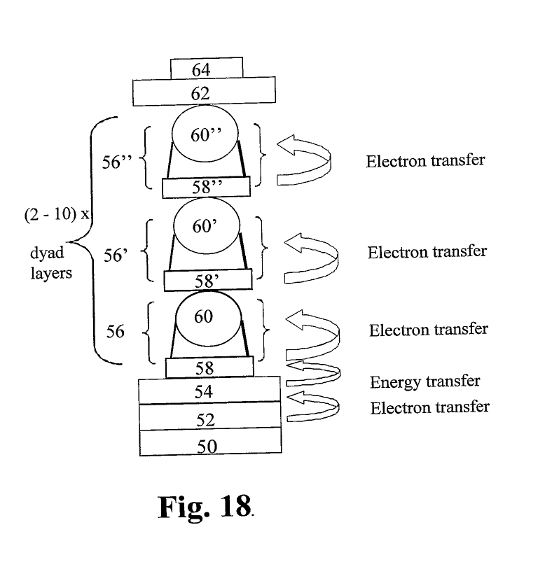

A photovoltaic device shown in FIG. 18 was manufactured as follows:

First, a substrate with an anode 50 was cleaned as described in Example 1. Then, HTL 52 and LAP layers 54 were prepared, in the indicated order, as described in Example 1. Next, multiple dyad layers 56, 56′ and 56″ were prepared by LB technique using the parameters mentioned in Example 1. The alternating dyad multilayer (2 to 10 layers) consisted of DHD6ee and TBD6he (or their metalloanalogues) and had sequence: porphyrin 58-fullerene 60-porphyrin 58′-fullerene 60′-porphyrin 58″-fullerene 60″.

After that, an ETL layer 62 was prepared as in Example 1. And finally, an aluminum cathode 64 was evaporated and deposited as in Example 1.

### Example 3

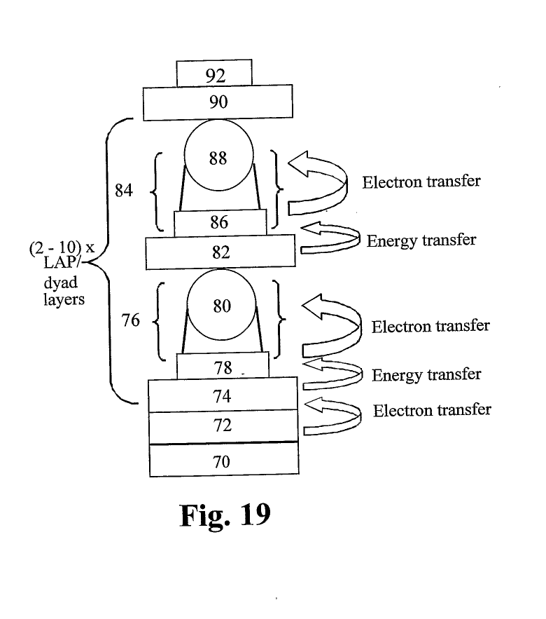

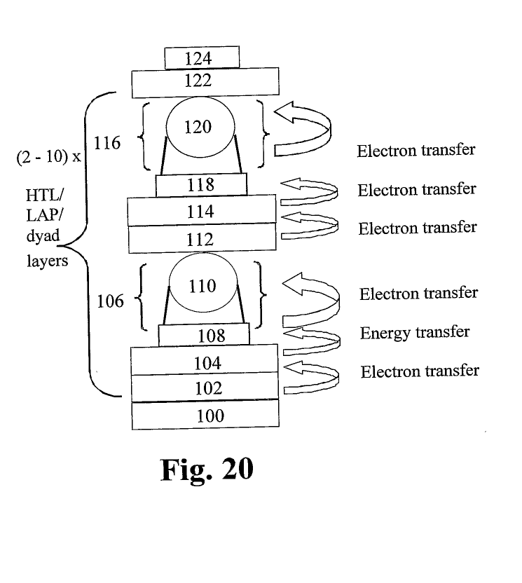

A photovoltaic device shown in FIG. 19 was manufactured as follows:

First, an anode-containing substrate 70 was cleaned as in Example 1. Then, an HTL layer 72 was prepared as described in Example 1. In the following step, a monolayer of light absorbing oligomer or polymer (LAP) 74 was deposited as in Example 1.

Then, a dyad monolayer of DHD6ee (or its analogues) 76, 78, 80 was deposited as in Example 1.

Next, preparations of the LAP layer 82 and the dyad layers 84, 86, 88 were repeated in order to obtain alternating multilayer film containing 2 to 10 LAP-dyad bilayers.

Next, an ETL layer 90 was prepared as in Example 1. And finally, a cathode 92 was evaporated onto the device as in Example 1.

### Example 4

A photovoltaic device shown in FIG. 20 was manufactured as follows.

First, an anode-containing substrate 100 was made ready for device manufacture as described in Example 1. Then, an HTL layer 102 was deposited onto the substrate as in Example 1. In the following steps, an LAP layer 104 was prepared as in Example 1 and a monolayer of DHD6ee (or its analogues) 106, 108, 110 was prepared as described in Example 1.

Next, preparations of the HTL 112, LAP 114 and dyad monolayers 116, 118, 120 were repeated in order to obtain 2 to 10 of HTL-LAP-dyad trilayers. In this multilayer film, all layers were prepared by the LB technique.

Next, an ETL 122 was prepared as described in Example 1. And finally, a cathode 124 was evaporated onto the device as in Example 1.

1. A photovoltaic device comprising
an anode;
a cathode spaced apart from the anode; and
at least one subcell disposed between the anode and the cathode, said subcell comprising a charge-transfer dyad with a light absorbing electron donor moiety and an electron acceptor moiety, which are covalently linked to each other in a non-flexible configuration and oriented such that each subcell is capable of performing primary photo-induced vectorial electron transfer between the donor and acceptor moieties in the direction from the anode to cathode, which is the natural function direction of the cell.

2. The photovoltaic device according to claim 1, wherein the light absorbing electron donor moiety and the electron acceptor moiety are covalently linked to each other by at least two chemical linkers which are covalently bonded both to the light adsorbing electron donor moiety and to the electron acceptor moiety.

3. The photovoltaic device according to claim 1, wherein the light absorbing electron donor moiety comprises a porphyrin or a phthalocyanine unit.

4. The photovoltaic device according to claim 1, wherein the electron acceptor moiety comprises a fullerene compound or its derivative.

5. The photovoltaic device according to claim 4, wherein the charge-transfer dyad comprises a fullerene compound covalently bonded to porphyrin or phtalocyanine or their derivatives by means of at least two linkers, e.g. molecular chains having 4 to 10 atoms between the electron donor and them acceptor.

6. The photovoltaic device according to claim 1, wherein either the end of the light absorbing electron donor moiety or that of the electron acceptor moiety are provided with a polar tail and the other moiety with a non-polar tail to facilitate the orientation of the molecules during deposition of the layer.

7. The photovoltaic device according to claim 1, wherein the charge-transfer dyad comprises of DHD6ee, TBD6he, TBD4he or Mn, Co, Ni, Cu, Zn and Fe analogues thereof.

8. The photovoltaic device according to claim 1, wherein the charge-transfer dyads comprise orientated Langmuir-Blodgett films.

9. The photovoltaic device according to claim 1, wherein a light absorbing oligomer or polymer (LAP) layer is placed adjacent to the donor moiety of the charge-transfer dyad in order to form a solar cell.

10. The photovoltaic device according to claim 9, wherein the light absorbing oligomer or polymer (LAP) layer is capable of transferring the excitation energy to the donor moieties of the charge-transfer dyad film for electrically exciting these.

11. The photovoltaic device according to claim 10, wherein the light absorbing oligomer or polymer (LAP) layer comprises of PVT1, PVT2, PVT3, or PVTP (FIG. 8).

12. The photovoltaic device according to claim 9, wherein a hole transfer layer (HTL) is placed adjacent to the light absorbing oligomer or polymer (LAP) layer, situated between this and the anode, and is capable of transferring electrons trough the LAP layer to the donor moiety of the charge-transfer dyad.

13. The photovoltaic device according to claim 12, wherein the hole transport layer (HTL) is formed of photoconductive organic semiconducting material.

14. The photovoltaic device according to claim 1, wherein the hole transport layer (HTL) is formed of an organic semiconducting material selected from the group consisting of polyacetylenes, polyparaphenylenes, polypyrroles, polythiophenes, polyparaphenyl vinylenes, polycarbazoles, polyheptadiynes, polyquinolines, and polyanilines.

15. The photovoltaic device according to claim 1, wherein the anode comprises a light transparent conductive oxide.

16. The photovoltaic device according to claim 1, wherein an electron transfer layer (ETL) is placed adjacent to the acceptor moiety of the charge-transfer dyad and it is located between the acceptor moiety and the cathode.

17. The photovoltaic device according to claim 1, comprising 2-19 multiple films of charge-transfer dyads, all oriented in the same direction.

18. The photovoltaic device according to claim 17, wherein a light absorbing oligomer or polymer (LAP) layer is adjacent to the donor moiety of the lowest charge-transfer dyad film.

19. The photovoltaic device according to claim 18, wherein the light absorbing oligomer or polymer (LAP) layer is adapted to transfer the excitation energy to the donor moieties of the lowest charge-transfer dyad film for exciting those electrically.

20. The photovoltaic device according to claim 17, wherein the electron transfer layer (ETL) is placed adjacent to the acceptor moiety of the highest charge-transfer dyad film and situated between this and the cathode.

21. The photovoltaic device according to claim 1, comprising 2-10 multiple subcells in series, each containing a charge-transfer dyad film, all oriented in the same direction, and a light absorbing oligomer or polymer (LAP) layer adjacent to the donor moiety of the charge-transfer dyad film.

22. The photovoltaic device according to claims 21, wherein the hole transfer layer (HTL) is placed adjacent to the lowest light absorbing oligomer or polymer (LAP) layer, situated between this and the anode, and is adapted for transferring electrons through the LAP layer to the donor moieties of the lowest charge-transfer dyad film.

23. The photovoltaic device according to claim 21, wherein the electron transfer layer (ETL) placed adjacent to the acceptor moiety of the highest charge-transfer dyad layer and situated between this and the cathode.

24. The photovoltaic device according to claim 1, comprising 2-10 multiple subcells in series, each containing a charge-transfer dyad film, all oriented in the same direction, a light absorbing oligomer or polymer (LAP) layer adjacent to the donor moiety of the charge-transfer dyad, and a hole transfer layer (HTL) adjacent to the light absorbing oligomer or polymer layer (LAP) and, lowest of those, situated between this and the anode.

25. A method of manufacturing a photovoltaic device, which method comprises the steps of
providing a first electrode layer,
providing a second electrode layer spaced apart from the first electrode layer, and
disposing a charge-transfer dyad between the anode and the cathode, the charge-transfer dyad comprising a light absorbing electron donor moiety and an electron acceptor moiety, which are covalently linked to each other in a non-flexible configuration and oriented such that each subcell is capable of performing primary photo-induced vectorial electron transfer between the donor and acceptor moieties in the direction from the anode to cathode, which is the natural function direction of the cell.

26. The method according to claim 25, comprising the steps of
a) providing a substrate;
b) depositing on the substrate a first electrode layer;
c) depositing a hole transfer layer,
d) depositing a light absorbing layer;
e) depositing on the light absorbing layer a charge-transfer dyad layer using the Langmuir-Blodgett technique;
f) optionally repeating step e), or repeating steps d) and e) or repeating steps c) to e) to provide a plurality of charge-transfer dyad layers optionally deposited on hole transfer layer(s) and light absorbing layer(s);
g) depositing on the top charge-transfer dyad layer an electron transfer layer; and
h) providing a second electrode layer on the electron transfer layer.

27. The method according to claim 26, wherein the hole transfer layer(s), the light absorbing layer(s) and the electron transfer layer(s) are deposited by a method selected from the group consisting of Langmuir-Blodgett technique, vacuum deposition, spin coating, organic vapor-phase deposition and inkjet printing.

28. The method according to claim 26, wherein the charge-transfer dyad layer is orientated using the Langmuir-Blodgett technique to provide for vectorial electron transfer between the donor and acceptor moieties in the direction from the anode to the cathode.

29. A method for producing electricity from light, comprising contacting with light a photovoltaic device comprising at least one light absorbing layer and, adjacent thereto, at least one subcell comprising a charge-transfer dyad with a light absorbing electron donor moiety and an electron acceptor moiety, which are covalently linked to each other in a non-flexible configuration and oriented such that each subcell is capable of performing primary photo-induced vectorial electron transfer between the donor and acceptor moieties in the direction from the anode to cathode, and recovering electricity from the device.
